(19) United States
(12) Patent Application Publication
(10) Pub. No.: US 2025/0105022 A1
(43) Pub. Date: Mar. 27, 2025

(54) METHOD OF MANUFACTURING SEMICONDUCTOR DEVICES AND VERTICAL POWER SEMICONDUCTOR DEVICE

(71) Applicant: Infineon Technologies AG, Neubiberg (DE)

(72) Inventors: Hans-Joachim Schulze, Taufkirchen (DE); Daniel Schlögl, Villach (AT); Josef Riss, Einoede (AT)

(21) Appl. No.: 18/886,502

(22) Filed: Sep. 16, 2024

(30) Foreign Application Priority Data
Sep. 25, 2023 (DE) 102023209358.8

(51) Int. Cl. H01L 21/324; C30B 29/06; H01L 21/268; H01L 21/322; H01L 29/739

(52) U.S. Cl. CPC H01L 21/324; C30B 29/06; H01L 21/268; H01L 21/3225; H10D 12/481

(57) ABSTRACT

A method of manufacturing semiconductor devices in a silicon MCZ (magnetic Czochralski) semiconductor body is proposed. The method includes processing the silicon MCZ semiconductor body by an oxidation process at temperatures exceeding 1150° C. and below 1220° C. Thereafter, platinum (Pt) is introduced into the silicon MCZ semiconductor body.

### TECHNICAL FIELD

The present disclosure relates to a method of manufacturing semiconductor devices, in particular to a method of manufacturing semiconductor devices in a silicon MCZ (magnetic Czochralski) semiconductor body. Moreover, the present disclosure relates to a vertical power semiconductor device.

### BACKGROUND

Semiconductor devices, e.g. power semiconductor diodes or field-effect controlled switching devices such as a junction field effect transistor (JFET), a metal oxide semiconductor field effect transistor (MOSFET) and an insulated gate bipolar transistor (IGBT), are typically used for various applications including but not limited to switches in power supplies and power converters, electric cars, air-conditioners. Such semiconductor devices are typically manufactured on wafer-level. With increasing wafer-size manufacturing costs per chip typically decrease. Larger silicon-wafers, i.e. silicon-wafers with a diameter of at least 12″, are currently only available as magnetic Czochralski grown silicon wafers. Silicon-wafers with a diameter of 8″ are also available as float zone grown silicon wafers, but are comparatively expensive and may have a comparatively large resistance variation due to striations. During single-crystal growth using the Czochralski (CZ) method and high temperature processing of the wafers, crystal defects such as crystal originated particles (COPs) or dislocation loops or slip lines may be formed. Agglomerated vacancy-related defects are known commonly as D-defects, or as COPs. Such defects may facilitate the formation of generation centers in the wafer resulting in an enhanced leakage current and weakening of later formed gate dielectrics.

Accordingly, there is a need to improve a method of manufacturing semiconductor devices in a silicon semiconductor body.

### SUMMARY

An example of the present disclosure relates to a method of manufacturing semiconductor devices in a silicon MCZ (magnetic Czochralski) semiconductor body. The method includes processing the silicon MCZ semiconductor body by an oxidation process at temperatures exceeding 1120° C. and below 1220° C. or at temperatures exceeding 1150° C. and below 1210° C. Thereafter, the method further includes introducing platinum into the silicon MCZ semiconductor body.

Another example relates to a vertical power semiconductor device. The vertical power semiconductor device includes a silicon MCZ (magnetic Czochralski) semiconductor body having a first surface and second surface opposite to the first surface. The vertical power semiconductor device further includes an anode being electrically connected to the silicon MCZ semiconductor body via the first surface. The vertical power semiconductor device further includes a cathode being electrically connected to the silicon MCZ semiconductor body via the second surface. The vertical power semiconductor device further includes a drift region in the silicon MCZ semiconductor body. The drift region includes platinum and oxygen. An oxygen concentration in the drift region has a value in a range from 1.0×10¹⁷ cm⁻³ to 4×10¹⁷ cm⁻³. A concentration of crystal originated particles (COPs) is at most 3000 per 300 mm wafer. The size of the COPs is, for example, between 0.1 μm and 0.3 μm.

Those skilled in the art will recognize additional features and advantages upon reading the following detailed description, and upon viewing the accompanying drawings.

### BRIEF DESCRIPTION OF THE DRAWINGS

The accompanying drawings are included to provide a further understanding of the embodiments and are incorporated in and constitute a part of this specification. The drawings illustrate examples of manufacturing semiconductor devices in a silicon MCZ semiconductor body and together with the description serve to explain principles of the examples. Further examples are described in the following detailed description and the claims.

FIGS. 1A and 1B are schematic views for illustrating a method of manufacturing semiconductor devices in a silicon MCZ semiconductor body.

FIGS. 2A to 2D are schematic views for illustrating configuration examples of furnace carriers of a thermal processing equipment and associated slip line arrangements in processed semiconductor bodies.

FIG. 3 is a schematic cross-sectional view for illustrating formation of semiconductor device elements in a silicon MCZ semiconductor body.

FIG. 4 is a schematic cross-sectional view for illustrating formation of a barrier structure in the silicon MCZ semiconductor body.

FIGS. 5A to 5C are schematic cross-sectional views for illustrating configuration examples of forming the barrier structure by forming a trench extending into the silicon MCZ semiconductor body.

FIG. 6 is a schematic top view for illustrating a configuration example of forming the barrier structure by a closed-loop trench in the silicon MCZ semiconductor body.

FIG. 7 is a schematic top view for illustrating a configuration example of an arrangement of a barrier sub-structure that is aligned to a support or contact point of a furnace carrier supporting the silicon MCZ semiconductor body.

FIG. 8 is a partial cross-sectional view for illustrating a configuration example of a vertical power device.

### DETAILED DESCRIPTION

In the following detailed description, reference is made to the accompanying drawings, which form a part hereof and in which are shown by way of illustrations specific examples of methods for manufacturing semiconductor devices in a silicon MCZ semiconductor body. It is to be understood that other examples may be utilized and structural or logical changes may be made without departing from the scope of the present disclosure. For example, features illustrated or described for one example can be used in conjunction with other examples to yield yet a further example. It is intended that the present disclosure includes such modifications and variations. The examples are described using specific language, which should not be construed as limiting the scope of the appending claims. The drawings are not scaled and are for illustrative purposes only. Corresponding elements are designated by the same reference signs in the different drawings if not stated otherwise.

The terms “having”, “containing”, “including”, “comprising” and the like are open, and the terms indicate the presence of stated structures, elements or features but do not preclude the presence of additional elements or features. The articles “a”, “an” and “the” are intended to include the plural as well as the singular, unless the context clearly indicates otherwise.

Ranges given for physical dimensions include the boundary values. For example, a range for a parameter y from a to b reads as a≤y≤b. The same holds for ranges with one boundary value like “at most” and “at least”.

The terms “on” and “over” are not to be construed as meaning only “directly on” and “directly over”. Rather, if one element is positioned “on” or “over” another element (e.g., a layer is “on” or “over” another layer or “on” or “over” a substrate), a further component (e.g., a further layer) may be positioned between the two elements (e.g., a further layer may be positioned between a layer and a substrate if the layer is “on” or “over” said substrate).

The adjectives “first”, “second” may be used herein for distinguishing between features that are designated by the same term, e.g. first/second modifications or first/second separation area. The adjectives do not preclude the sequence of manufacture of the features. Thus, the first modifications may be formed before or after forming the second modifications.

The term “crystal originated particle” (COPs) as used in this specification intends to describe a void in the semiconductor material which is typically formed by an agglomeration of vacancies during crystal growth and may include an outer silicon oxide shell. The risk of forming slip lines in the semiconductor substrate typically increases with the concentration and size of the COPs. Furthermore, COPs which are decorated with in-diffusing heavy metals, like e.g. Fe, Cu, Ni, may act as generation centers enhancing the leakage current of the devices. The diameter of the COPs is typically below about 300 nm, more typically below 20 nm.

The description and drawings merely illustrate the principles of the disclosure. Furthermore, all examples recited herein are principally intended expressly to be only for illustrative purposes to aid the reader in understanding the principles of the disclosure and the concepts contributed by the inventor(s) to furthering the art. All statements herein reciting principles, aspects, and examples of the disclosure, as well as specific examples thereof, are intended to encompass equivalents thereof.

It is to be understood that the disclosure of multiple acts, processes, operations, steps or functions disclosed in the specification or claims may not be construed as to be within the specific order, unless explicitly or implicitly stated otherwise, e.g. by expressions like “thereafter”, for instance for technical reasons. Therefore, the disclosure of multiple acts or functions will not limit these to a particular order unless such acts or functions are not interchangeable for technical reasons. Furthermore, in some examples a single act, function, process, operation or step may include or may be broken into multiple sub-acts, -functions, -processes, -operations or -steps, respectively. Such sub acts may be included and part of the disclosure of this single act unless explicitly excluded.

An example of the present disclosure relates to a method of manufacturing semiconductor devices in a silicon MCZ (magnetic Czochralski) semiconductor body. The method may include processing the silicon MCZ semiconductor body by an oxidation process at temperatures exceeding 1120° C. and below 1230° C. or at temperatures exceeding 1150° C. and below 1210° C. Thereafter, the method may further include introducing platinum (Pt) into the silicon MCZ semiconductor body.

The semiconductor devices may be arranged in dies. Each of the semiconductor devices may be an integrated circuit, or a discrete semiconductor device, for example. The integrated circuit or semiconductor device may be or may include a power semiconductor device, e.g. a vertical power semiconductor device having a load current flow between the first surface and the second surface. The dies may be used in automotive, industrial power control, power management, sensing solutions and security in Internet of Things applications, for example. The dies may be or may include a power semiconductor diode, or a reverse conducting power semiconductor insulated gate bipolar transistor (power semiconductor RC-IGBT). For example, a power semiconductor device in the dies may be configured to conduct currents of more than 1 A or more than 10 A or even more than 30 A. The semiconductor device in the dies may be further configured to block voltages between load terminals, e.g. between emitter and collector of an RC-IGBT, or between cathode and anode of a diode, in the range of several tens, or several hundreds, or up to several thousands of volts, e.g. 30V, 40V, 60V, 80V, 100V, 400 V, 650V, 1.2 kV, 1.7 kV, 3.3 kV, 4.5 kV, 5.5 kV, 6 kV, 6.5 kV, 10 kV.

During the oxidation process of the silicon MCZ semiconductor body, interstitial silicon atoms may be generated at the oxidizing surface and diffuse into the crystalline silicon MCZ semiconductor body. The generated interstitial silicon atoms moving into a bulk of the crystalline silicon MCZ semiconductor body occupy vacancies in the crystal lattice, thereby dissolving COPs by filling accumulations of vacancies or voids of the COPs. The process may also lead to a breakup of an oxide layer lining an inner surface of the COPs. For that the temperature must be high enough, so that this oxide layer will be dissolved which depends on the height of the oxygen concentration within the wafer. For example, the oxidation process may be carried out for a duration of at least 20 minutes, or even at least 1 hour. According to an example, the oxidation process may be carried out in a wet ambient.

For example, the platinum may be introduced into the silicon MCZ semiconductor body by diffusion from a Pt-silicide layer and/or platinum implantation followed by annealing. Introduction of platinum may allow for improving the switching characteristics by adjusting the lifetime of the minority charge carriers, for example.

By combining the oxidation process at temperatures exceeding 1120° C. and below 1230° C. or at temperatures exceeding 1150° C. and below 1210° C. with a later introduction of platinum, the COPs may be effectively dissolved, but on the other hand so-called slip lines can be generated at such high temperatures which can act as getter centers for platinum resulting in higher leakage currents of the devices.

For example, the method may further include forming semiconductor device elements in the silicon MCZ semiconductor body at a first surface of the silicon MCZ semiconductor body by processing the silicon MCZ semiconductor body at the first surface. Forming semiconductor device elements in the silicon MCZ semiconductor body at the first surface may be carried out after the oxidation process at temperatures exceeding 1120° C. and below 1230° C. or at temperatures exceeding 1150° C. and below 1210° C. and before introducing platinum into the silicon MCZ semiconductor body from the frontside or the backside of the wafer.

The first surface may be a front surface or a top surface of the silicon MCZ semiconductor body, and the second surface may be a back surface or a rear surface of the silicon MCZ semiconductor body, for example. High-temperature processing at temperatures exceeding 600° C. of the dies at the first surface of the silicon MCZ semiconductor body may be finalized or completed before introducing platinum into the silicon MCZ semiconductor body and/or before processing the silicon MCZ semiconductor body at a second surface opposite to the first surface, for example.

Forming the semiconductor device elements may include processes for defining the dies adjoining to the first surface of silicon MCZ semiconductor body. The processes may include, for example, at least one doping process for forming doped regions in the silicon MCZ semiconductor body at the first surface. The at least one doping process may include an ion implantation process followed by a thermal activation of dopants, a diffusion process introducing the dopants into the silicon MCZ semiconductor body from a dopant source (e.g. solid or gaseous diffusion source), an in-situ doping process when forming a semiconductor layer, e.g. by a layer deposition process, on a semiconductor base substrate such as a wafer. The exemplary doping processes may be combined in any way and may be repeated in any way, e.g. depending on a desired number and profile of the doped regions that are to be formed in the silicon MCZ semiconductor body at the first surface. Exemplary doped regions are emitter and collector regions, body region(s), body contact region(s), field stop region(s), anode region(s), cathode region(s). The processes may also include trench etch processes. The trench etch processes may be used to form trenches such as gate electrode trenches, field electrode trenches, multi-electrode trenches (e.g. combining gate and field electrodes in one trench), trenches for edge termination structures, contact trenches for providing an electric contact to doped regions in the silicon MCZ semiconductor body. The processes may also include forming insulating layer(s), conductive layer(s), or any combination thereof, in the trenches. Exemplary insulating or conductive layers include, inter alia, gate or field electrodes by doped semiconductor layers (e.g. doped polycrystalline silicon, or metal, or metal alloy), oxide layers (e.g. silicate glass, deposited SiO₂, thermal SiO₂), nitride layers (e.g., Si₃N₄), high-k dielectric layers, low-k dielectric layers, dielectric spacers, or any combination thereof.

For example, the method may further include forming a wiring area over the first surface of the silicon MCZ semiconductor body after introducing platinum into the silicon MCZ semiconductor body.

Forming the wiring area may include forming one or more than one, e.g. two, three, four or even more wiring levels. Each wiring level may be formed by a single one or a stack of conductive layers, e.g. metal layer(s). For example, the wiring levels may include at least one of Cu, Au, AlCu, Ag, or alloys thereof. The wiring levels may be lithographically patterned, for example. Between stacked wiring levels, an interlayer dielectric structure may be formed. Openings may be formed in the interlayer dielectric structure for electrically interconnecting different wiring layers. For example, contact plug(s), or contact via(s) or contact line(s) may be formed in the openings in the interlayer dielectric structure to electrically connect parts, e.g. metal lines or contact areas, of different wiring levels to one another. The wiring area may be arranged over an active area of dies formed in the silicon MCZ semiconductor body. In some examples, apart from the active area, the dies may also include an edge termination area that at least partly surrounds the active area. The edge termination area may include a termination structure. In a blocking mode or in a reverse biased mode of the semiconductor devices formed in the dies, the blocking voltage between the active area and a field-free region laterally drops across the termination structure. The termination structure may include a junction termination extension (JTE) with or without a variation of lateral doping (VLD), one or more laterally separated guard rings, or any combination thereof, for example.

For example, the method may further include forming a barrier structure in the silicon MCZ semiconductor body before the oxidation process at temperatures exceeding 1120° C. and below 1230° C. or at temperatures exceeding 1150° C. and below 1210° C. The barrier structure may be configured to stop propagation of slip lines. The barrier structure may hinder slip lines from undesired propagation from their region of origin, e.g. support points of a furnace carrier supporting the silicon MCZ semiconductor body, into the active area of the semiconductor devices, for example. Slip lines in the active area of the semiconductor devices may lead to undesired electric effects such as reduction of minority carrier lifetime and/or increase of leakage currents caused by decoration of the slip lines with heavy metal atoms.

For example, the silicon MCZ semiconductor body may include a die area comprising active areas of the semiconductor devices. The silicon MCZ semiconductor body may further include a perimeter area arranged between the die area and an edge of the silicon MCZ semiconductor body. The barrier structure may be arranged in the perimeter area outside of the die area.

For example, a lateral distance between the barrier structure and an edge of the silicon MCZ semiconductor body may have a value in a range from 500 μm to 5 mm, or in a range from 1 mm to 3 mm. This may allow for minimizing undesired chip area loss and may further allow for minimizing undesired large widths or lateral extensions of the barrier structures. A certain width or lateral extension of the barrier structure allows for effectively hindering slip line propagation depending on the distance from the origin of the slip lines, for example.

For example, the barrier structure may be a trench barrier structure. The trench barrier structure may partly or fully penetrate the silicon MCZ semiconductor body. For example, the trench(es) of the trench barrier structure may be formed by trench etching or a laser processing. A surface of the trench(es) may subsequently be treated by an overetch process and/or by hydrogen treatment or by further etch processes. The trench(es) may stop the propagation of the slip lines impinging on the trench(es), for example.

For example, a width of the barrier structure may have a value in a range from 100 nm to 10 μm, or in a range from 200 nm to 5 μm. For example, the barrier structure may partly penetrate the silicon MCZ semiconductor body and may have a circular shape. The barrier structure may extend, at least in part, in parallel to a perimeter or edge of the silicon MCZ semiconductor body.

For example, the barrier structure may include n barrier sub-structures laterally spaced from each other, n being an integer in a range from 2 to 4. The number of barrier sub-structures may depend on the number of support or contact points between the silicon MCZ semiconductor body and a furnace carrier for carrying out the oxidation process according to the configuration examples described herein.

For example, an arrangement of the barrier sub-structures is configured to be aligned to support points of a furnace carrier supporting the silicon MCZ semiconductor body during the oxidation process at temperatures exceeding 1120° C. and below 1230° C. or at temperatures exceeding 1150° C. and below 1210° C. The arrangement may depend on the type of furnace used for the oxidation process, e.g. horizontal furnace or vertical furnace.

For example, a lateral extension of each of the barrier sub-structures exceeds three times a lateral distance to the edge of the silicon MCZ semiconductor body plus a lateral extension of a corresponding one of the support points. For example, a shape of the barrier sub-structures may, for example, be adapted to a wafer diameter of the silicon MCZ semiconductor body, and may, for example, be slightly curved in the area of the contact or support points. By adjusting a lateral extension (e.g. in the azimuthal direction) of the barrier sub-structures a possible misalignment can be taken into account, and also the lateral widening of the slip lines on their way from the point of origin to the barrier sub-structures. For example, a lateral extension of the barrier sub-structures may have a value in a range from 5 mm to 2 cm depending on the lateral distance to the edge of the silicon MCZ semiconductor body.

For example, forming the barrier structure may include forming a trench extending into the silicon MCZ semiconductor body from a first surface of the silicon MCZ semiconductor body. The trench may be formed by laser processing and/or etching.

For example, the method may further include reducing a thickness of the silicon MCZ semiconductor body by removing material of the silicon MCZ semiconductor body from a second surface opposite to the first surface. The thickness may be reduced by abrasive machining process(es), e.g. grinding, and/or etch process(es). Reducing the thickness may also be used for forming a stabilizing ring at the wafer edge for thin wafer processing, for example.

For example, the material of the silicon MCZ semiconductor body may be removed from the second surface at least up to a bottom side of the trench.

For example, forming the barrier structure may include forming a trench extending into the silicon MCZ semiconductor body from the second surface of the MCZ semiconductor body. For example, the trenches may be formed, if available, in the area of a stabilizing ring geometry and the technology edge exclusion, if available. This may allow for avoiding undesired interactions with the entire FEOL process chain. For example, the trenches may, for example, be placed where the stabilizing ring for thin wafer processing will be ground at a later stage. Thereby, no extra chip area has to be sacrificed for the barrier structure, which may be instead used for the semiconductor devices in the dies. For technologies not based on stabilizing rings, e.g. thick wafer technologies, the barrier structure may be positioned under in the area of the technology edge exclusion, for example.

For example, the method may further include reducing a thickness of the silicon MCZ semiconductor body by removing material of the silicon MCZ semiconductor body from the second surface opposite to the first surface in an area where the trench is arranged.

For example, forming the barrier structure may include forming one or more through holes in the silicon MCZ semiconductor body.

For example, forming the barrier structure may include forming a closed-loop trench in the silicon MCZ semiconductor body. The closed-loop trench may, at least in part, extend in parallel to an edge of the silicon MCZ semiconductor body, for example.

Details with respect to structure, or function, or technical benefit of features described above with respect to a method of manufacturing semiconductor devices in the silicon MCZ semiconductor body likewise apply to the exemplary devices, e.g. diodes or RC-IGBTs, described herein.

According to a configuration example, a vertical power semiconductor device may be formed by any of the methods described herein. The vertical power semiconductor device may include a drift region including platinum and oxygen. An oxygen concentration in the drift region may have a value in a range from 1.0×10¹⁷ cm⁻³ to 4×10¹⁷ cm⁻³. The oxygen concentration may be achieved by the oxidation process according to the configuration examples described herein. The vertical power semiconductor device may be a diode or a reverse conducting insulated gate bipolar transistor.

A configuration example of a vertical power semiconductor device may include a silicon MCZ, magnetic Czochralski, semiconductor body having a first surface and second surface opposite to the first surface. The vertical power semiconductor device may further include an anode being electrically connected to the silicon MCZ semiconductor body via the first surface. The vertical power semiconductor device may further include a cathode being electrically connected to the silicon MCZ semiconductor body via the second surface. The vertical power semiconductor device may further include a drift region in the silicon MCZ semiconductor body. The drift region may include platinum and oxygen. An oxygen concentration in the drift region may have a value in a range from 1.0×10¹⁷ cm⁻³ to 4×10¹⁷ cm⁻³. A concentration of crystal originated particles (COPs) may be at most 3000 in each 300 mm wafer.

For example, the oxygen concentration may have a maximum gradient in a range of 15 μm below the anode of 2×10²¹ cm⁻⁴ or below 5×10²⁰ cm⁻⁴.

More details and aspects are mentioned in connection with the examples described above or below. Processing a silicon MCZ semiconductor body may comprise one or more optional additional features corresponding to one or more aspects mentioned in connection with the proposed concept or one or more examples described above or below.

The description and drawings merely illustrate the principles of the disclosure. Furthermore, all examples recited herein are principally intended expressly to be only for illustrative purposes to aid the reader in understanding the principles of the disclosure and the concepts contributed by the inventor(s) to furthering the art. All statements herein reciting principles, aspects, and examples of the disclosure, as well as specific examples thereof, are intended to encompass equivalents thereof.

In the following, further examples of structural or process features are explained in connection with the accompanying drawings. Functional and structural details described with respect to the examples above shall likewise apply to the exemplary embodiments illustrated in the figures and described further below.

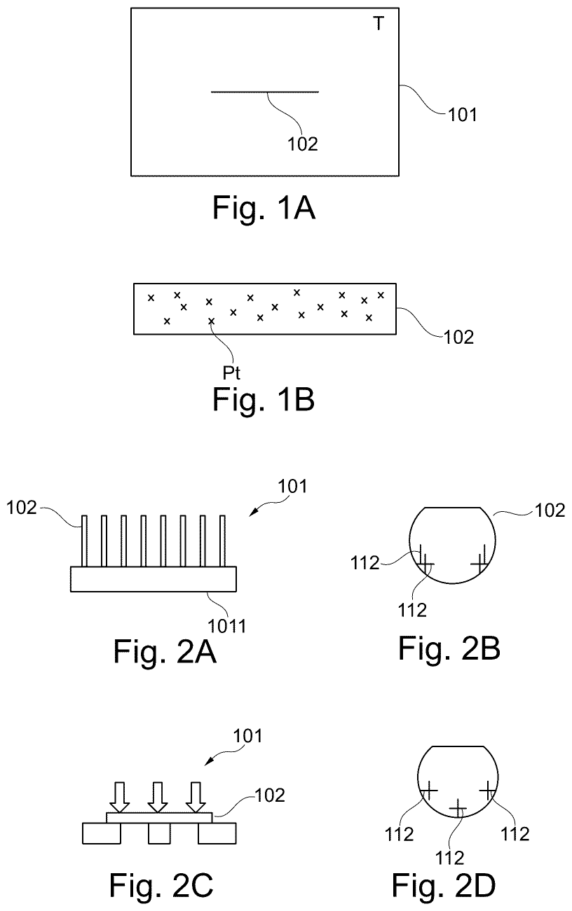

FIGS. 1A and 1B schematically and exemplarily show views for illustrating process features of manufacturing semiconductor devices in a silicon MCZ, magnetic Czochralski semiconductor body 102.

The view of FIG. 1A shows a thermal processing equipment 101, e.g. a horizontal or vertical furnace, for illustrating a feature of processing the silicon MCZ semiconductor body 102 by an oxidation process at temperatures T exceeding 1120° C. and below 1230° C. or at temperatures exceeding 1150° C. and below 1210° C. The view is simplified, inter alia, by illustrating a single silicon MCZ semiconductor body 102. In the thermal processing equipment 101, a plurality of silicon MCZ semiconductor bodies 102 may be processed in parallel by arranging the plurality of silicon MCZ semiconductor bodies 102 on a furnace carrier, for example.

After the oxidation process illustrated in FIG. 1A one or more processes may be carried out. For example, the one or more processes may include FEOL (front end of line) processes for forming semiconductor device elements in the silicon MCZ semiconductor body 102.

After the one or more processes and referring to FIG. 1B, platinum (Pt) is introduced into the silicon MCZ semiconductor body 102.

After the introducing platinum into the silicon MCZ semiconductor body 102 as illustrated in FIG. 1B one or more processes may be carried out. For example, the one or more processes may include processes for forming a wiring area over the silicon MCZ semiconductor body 102, for example.

The schematic side view of FIG. 2A illustrates a configuration example of a thermal processing equipment 101 implemented as a horizontal furnace including a horizontal furnace carrier 1011 configured to support silicon MCZ semiconductor bodies 102. Referring to the schematic top view of the MCZ semiconductor body 102 of FIG. 2B, thermal processing in the thermal processing equipment 101 may lead to slip lines 112 emerging at support or contact points between the silicon MCZ semiconductor bodies 102 and the horizontal furnace carrier 1011.

The schematic side view of FIG. 2C illustrates a configuration example of a thermal processing equipment 101 implemented as a vertical furnace including a vertical furnace carrier 1012 configured to support silicon MCZ semiconductor bodies 102. Contact regions between the silicon MCZ semiconductor bodies 102 and the vertical furnace carrier 1012 are indicated by arrows. Referring to the schematic top view of the MCZ semiconductor body 102 of FIG. 2D, thermal processing in the thermal processing equipment 101 may lead to slip lines 112 emerging at support or contact points between the silicon MCZ semiconductor bodies 102 and the horizontal furnace carrier 1011.

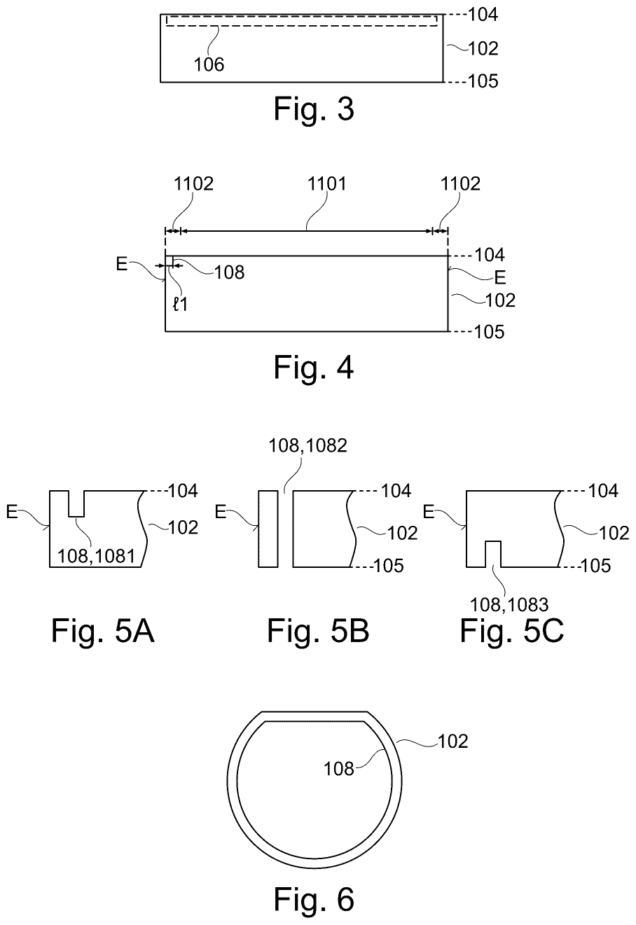

The schematic cross-sectional view of FIG. 3 is a simplified and exemplary illustration of forming semiconductor device elements 106 in the silicon MCZ semiconductor body 102 at the first surface 104 of the silicon MCZ semiconductor body 102 by processing the silicon MCZ semiconductor body 102 at the first surface 104. The semiconductor device elements 106 in the silicon MCZ semiconductor body 102 are illustrated in a simplified manner by a dashed line surrounding the part of the silicon MCZ semiconductor body 102 where the semiconductor device elements are formed. Forming the semiconductor device elements 106 in the silicon MCZ semiconductor body 102 at the first surface 104 may be carried out after the oxidation process at temperatures exceeding 1120° C. and below 1230° C. or at temperatures exceeding 1150° C. and below 1210° C. (see, for example, FIG. 1A) and before introducing platinum into the silicon MCZ semiconductor body 102 (see, for example, FIG. 1B).

The schematic cross-sectional view of FIG. 4 is a simplified and exemplary illustration of forming a barrier structure 108 in the silicon MCZ semiconductor body 102 before the oxidation process at temperatures exceeding 1150° C. and below 1220° C. (see, for example, FIG. 1A). The barrier structure 108 is configured to stop propagation of slip lines. The silicon MCZ semiconductor body 102 includes a die area 1101 with active areas of the semiconductor devices, and a perimeter area 1102 arranged between the die area 1101 and an edge E of the silicon MCZ semiconductor body 102. Wafer dicing at a later stage may lead to separation of the semiconductor devices (dies) from one another. The barrier structure 108 is arranged in the perimeter area 1102 outside of the die area 1101. For example, the perimeter area may be an area stabilizer ring geometry and/or a technology edge exclusion are located. For example, a lateral distance 11 between the barrier structure 108 and the edge E of the silicon MCZ semiconductor body 102 may have a value in a range from 500 μm to 5 mm.

Referring to the schematic cross-sectional view of FIG. 5A, forming the barrier structure 108 may include forming a trench 1081 extending into the silicon MCZ semiconductor body 102 from the first surface 104 of the silicon MCZ semiconductor body 102.

Referring to the schematic cross-sectional view of FIG. 5B, forming the barrier structure 108 may include forming a through hole 1082 in the silicon MCZ semiconductor body 102. The through hole 1082 penetrates the silicon MCZ semiconductor body 102 from the first surface 104 to the second surface 105 of the silicon MCZ semiconductor body 102.

Referring to the schematic cross-sectional view of FIG. 5C, forming the barrier structure 108 may include forming a trench 1083 extending into the silicon MCZ semiconductor body 102 from a second surface 105 of the silicon MCZ semiconductor body 102.

The schematic top view of FIG. 6 is based on any of the configuration examples of FIG. 5A or FIG. 5C and illustrates forming the barrier structure 108 by a closed-loop trench in the silicon MCZ semiconductor body 102.

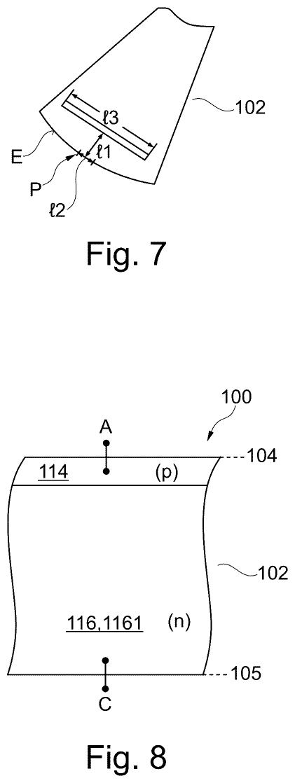

The schematic top view of FIG. 7 illustrates a configuration example of an arrangement of a barrier sub-structure 1084 that is aligned to a support or contact point P of a furnace carrier supporting the silicon MCZ semiconductor body 102 during the oxidation process at temperatures exceeding 1120° C. and below 1230° C. or at temperatures exceeding 1150° C. and below 1210° C. The top view of FIG. 7 illustrates a part of the silicon MCZ semiconductor body 102. The number of barrier sub-structures 1084 may depend on a number of support or contact points P of the furnace carrier supporting the silicon MCZ semiconductor body 102 during the oxidation process. For example, a lateral extension 13 of each of the barrier sub-structures 1084 may exceed three times a lateral distance 11 to the edge E of the silicon MCZ semiconductor body 102 plus a lateral extension 12 of a corresponding one of the support points, for example.

A partial cross-sectional view of a configuration example of a vertical power semiconductor device 100 is illustrated in FIG. 8. The vertical power semiconductor device 100 may be a diode or a reverse conducting insulated gate bipolar transistor, for example.

The vertical power semiconductor device 100 may include a silicon MCZ semiconductor body 102 having a first surface 104 and second surface 104 opposite to the first surface 104. The vertical power semiconductor device 100 further includes an anode A electrically connected to an anode region 114 in the silicon MCZ semiconductor body 102 via the first surface 104. The vertical power semiconductor device 100 further includes a cathode C electrically connected to a cathode region 116 in the silicon MCZ semiconductor body 102 via the second surface 105. The vertical power semiconductor device 100 further includes a drift region 1161 in the silicon MCZ semiconductor body 102. The drift region 1161 may be part of the cathode region 116. The cathode region 116 may include further doped regions, e.g. a field stop region and/or cathode contact region. The drift region 1161 may include platinum and oxygen. An oxygen concentration in the drift region 1161 may have a value in a range from 1.0×10¹⁷ cm⁻³ to 4×10¹⁷ cm⁻³. A concentration of crystal originated particles (COPs) may be at most 3000 in each 300 mm wafer. Thus, an upper limit for the average number of COPs within the power semiconductor device 100 may be calculated from the die size of the power semiconductor device 100 and its share of the total wafer surface area (300 mm×300 mm×π). Alternatively, an upper limit for the average number of COPs within the power semiconductor device 100 may be calculated by dividing the upper limit for the wafer given above (3000 COPs per wafer) by the number of power semiconductor devices 100 sliced from the wafer. It has to be mentioned, that the number of COPs per power semiconductor device 100 may vary significantly depending of the position on the wafer from where the respective power semiconductor device 100 is sliced.

The aspects and features mentioned and described together with one or more of the previously described examples and figures, may as well be combined with one or more of the other examples in order to replace a like feature of the other example or in order to additionally introduce the feature to the other example.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A method of manufacturing semiconductor devices in a silicon MCZ (magnetic Czochralski) semiconductor body, the method comprising:
processing the silicon MCZ semiconductor body by an oxidation process at temperatures exceeding 1120° C. and below 1230° C.; and
after the processing, introducing platinum (Pt) into the silicon MCZ semiconductor body.

2. The method of claim 1, further comprising:
forming semiconductor device elements in the silicon MCZ semiconductor body at a first surface of the silicon MCZ semiconductor body by processing the silicon MCZ semiconductor body at the first surface,
wherein forming the semiconductor device elements in the silicon MCZ semiconductor body at the first surface is carried out after the oxidation process and before introducing the platinum into the silicon MCZ semiconductor body.

3. The method of claim 1, further comprising:
forming a wiring area over a first surface of the silicon MCZ semiconductor body after introducing the platinum into the silicon MCZ semiconductor body.

4. The method of claim 1, further comprising:
forming a barrier structure in the silicon MCZ semiconductor body before the oxidation process, wherein the barrier structure is configured to stop propagation of slip lines.

5. The method of claim 4, wherein the silicon MCZ semiconductor body includes a die area comprising active areas of the semiconductor devices, and a perimeter area arranged between the die area and an edge of the silicon MCZ semiconductor body, and wherein the barrier structure is arranged in the perimeter area outside of the die area.

6. The method of claim 4, wherein a lateral distance between the barrier structure and an edge of the silicon MCZ semiconductor body is in a range from 500 μm to 5 mm.

7. The method of claim 4, wherein the barrier structure is a trench barrier structure.

8. The method of claim 7, wherein a width of the barrier structure is in a range from 100 nm to 10 μm.

9. The method of claim 7, wherein the barrier structure includes n barrier sub-structures laterally spaced from each other, n being an integer in a range from 2 to 4.

10. The method of claim 9, wherein an arrangement of the barrier sub-structures is configured to be aligned to support points of a furnace carrier supporting the silicon MCZ semiconductor body during the oxidation process.

11. The method of claim 10, wherein a lateral extension of each of the barrier sub-structures exceeds three times a lateral distance to an edge of the silicon MCZ semiconductor body plus a lateral extension of a corresponding one of the support points.

12. The method of claim 4, wherein forming the barrier structure comprises forming a trench extending into the silicon MCZ semiconductor body from a first surface of the silicon MCZ semiconductor body.

13. The method of claim 12, wherein the trench is formed by laser processing and/or etching.

14. The method of claim 12, further comprising:
reducing a thickness of the silicon MCZ semiconductor body by removing material of the silicon MCZ semiconductor body from a second surface opposite to the first surface.

15. The method of claim 14, wherein the material of the silicon MCZ semiconductor body is removed from the second surface at least up to a bottom side of the trench.

16. The method of claim 4, wherein forming the barrier structure comprises forming a trench extending into the silicon MCZ semiconductor body from a second surface of the MCZ semiconductor body opposite a first surface of the MCZ semiconductor body.

17. The method of claim 16, further comprising:
reducing a thickness of the silicon MCZ semiconductor body by removing material of the silicon MCZ semiconductor body from the second surface in an area where the trench is arranged.

18. The method of claim 4, wherein forming the barrier structure comprises forming one or more through holes in the silicon MCZ semiconductor body.

19. The method of claim 4, wherein forming the barrier structure comprises forming a closed-loop trench in the silicon MCZ semiconductor body.

20. A vertical power semiconductor device, comprising:
a drift region including platinum and oxygen,
wherein an oxygen concentration in the drift region is in a range from 1.0×10¹⁷ cm⁻³ to 4×10¹⁷ cm⁻³.

21. The vertical power semiconductor device of claim 20, wherein the vertical power semiconductor device is a diode or a reverse conducting insulated gate bipolar transistor.

22. A vertical power semiconductor diode, comprising:
a silicon MCZ (magnetic Czochralski) semiconductor body having a first surface and second surface opposite to the first surface;
an anode electrically connected to the silicon MCZ semiconductor body via the first surface;
a cathode electrically connected to the silicon MCZ semiconductor body via the second surface;
a drift region in the silicon MCZ semiconductor body, the drift region including platinum and oxygen,
wherein an oxygen concentration in the drift region is in a range from 1.0×10¹⁷ cm⁻³ to 4×10¹⁷ cm⁻³,
wherein a concentration of crystal originated particles (COPs) is at most 3000 per 300 mm wafer.

23. The vertical power semiconductor device of claim 22, wherein the oxygen concentration has a maximum gradient in a range of 15 μm below the anode of 2×10²¹ cm⁻⁴.
